(19) United States
(12) Patent Application Publication
(10) Pub. No.: US 2023/0118200 A1
(43) Pub. Date: Apr. 20, 2023

(54) OPTICAL MEMBER AND LIGHT-EMITTING DEVICE

(71) Applicant: NICHIA CORPORATION, Anan-shi (JP)

(72) Inventor: Toshiaki YAMASHITA, Komatsushima-shi (JP)

(21) Appl. No.: 18/047,989

(22) Filed: Oct. 19, 2022

(30) Foreign Application Priority Data
Oct. 20, 2021 (JP) 2021-171592

(51) Int. Cl. F21V 9/30

(52) U.S. Cl. CPC F21V 9/30

(57) ABSTRACT

An optical member includes a first wavelength conversion member including a wavelength conversion portion and a ceramic portion surrounding lateral surfaces of the wavelength conversion portion, and a light shielding film arranged on an outer lateral surface of the first wavelength conversion member.

### CROSS-REFERENCE TO RELATED APPLICATION

This application claims priority to Japanese Patent Application No. 2021-171592, filed on Oct. 20, 2021, the disclosure of which is hereby incorporated herein by reference in its entirety.

### BACKGROUND

The present invention relates to an optical member and a light-emitting device including an optical member.

There is proposed a known light-emitting device including a semiconductor laser or the like as an excitation light source and generating illumination or the like using excitation light emitted from the excitation light source.

In such a light-emitting device, for example, for wavelength conversion of the excitation light emitted from the excitation light source, a light-emitting unit including a phosphor and a wavelength conversion member including a reflection film surrounding the light-emitting unit are disposed to the front of the excitation light source. A light absorbing film is disposed on the surface of the wavelength conversion member on the opposite side to the excitation light source. A configuration has been proposed in which, for suppressing the effects of reflected light, reflected light from a light-transmitting lens is absorbed by the light absorbing film (see Japanese Patent Publication No. 2016-66480).

### SUMMARY

With an optical member including a wavelength conversion member configured as such, there is a possibility of light leaking from a region other than the desired light extraction region. Thus, there is a demand for an optical member that can effectively reduce or prevent such light leakage.

An optical member according to an embodiment includes a first wavelength conversion member including a wavelength conversion portion and a ceramic portion surrounding lateral surfaces of the wavelength conversion portion, and a light shielding film arranged on an outer lateral surface of the first wavelength conversion member. Also, a light-emitting device according to an embodiment includes the optical member described above, a package including a base portion and a wall portion extending from the base portion, and a plurality of semiconductor laser elements disposed in a space defined by the package and the optical member.

According to an embodiment of the present invention, an optical member which can effectively reduce or prevent light leakage can be provided.

### BRIEF DESCRIPTION OF THE DRAWINGS

FIG. 1A is a schematic plan view of an optical member of a first embodiment.

FIG. 1B is a schematic cross-sectional view taken along line IB-IB′ in FIG. 1A.

FIG. 1C is a schematic cross-sectional view of the optical member including a light-transmitting member according to the first embodiment.

FIG. 2A is a schematic bottom view illustrating a wiring layer of a first wavelength conversion member of the optical member of the first embodiment.

FIG. 2B is a schematic plan view illustrating a wiring layer of the light-transmitting member of the optical member of the first embodiment.

FIG. 2C is a schematic plan view for describing a wiring connection state in a case in which the first wavelength conversion member and the light-transmitting member of FIGS. 2A and 2B are overlapped.

FIG. 3A is a schematic plan view of an optical member of a second embodiment.

FIG. 3B is a schematic cross-sectional view taken along line IIIB-IIIB′ in FIG. 3A.

FIG. 4A is a schematic bottom view illustrating a wiring layer of a first wavelength conversion member and a second wavelength conversion member of the optical member of the second embodiment.

FIG. 4B is a schematic plan view illustrating a wiring layer of a light-transmitting member of the optical member of the second embodiment.

FIG. 5A is a schematic perspective view of a light-emitting device of a third embodiment.

FIG. 5B is a schematic cross-sectional view taken along line VB-VB′ in FIG. 5A.

FIG. 6A is a schematic perspective view of a light-emitting device of a fourth embodiment.

FIG. 6B is a schematic plan view of the light-emitting device of FIG. 6A.

FIG. 6C is a schematic plan view illustrating a wiring connection state of the light-emitting device of FIG. 6A.

FIG. 6D is a schematic plan view illustrating a modified example of the wiring connection state of FIG. 6C.

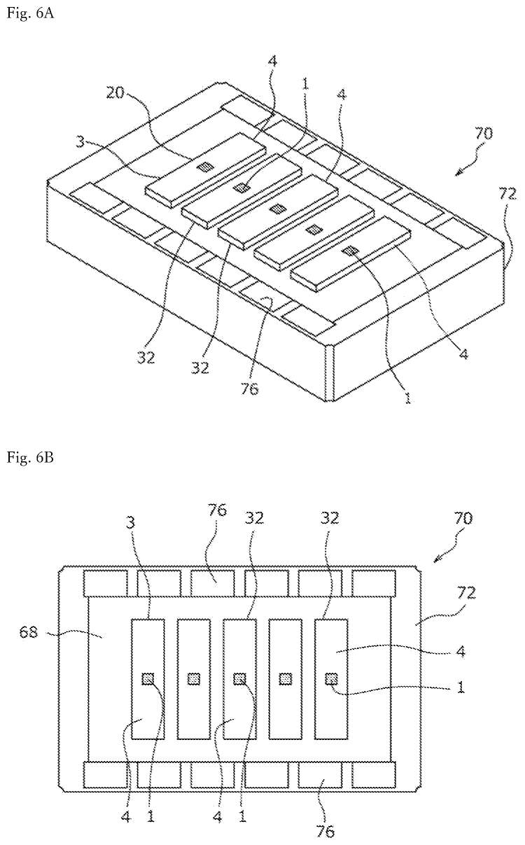

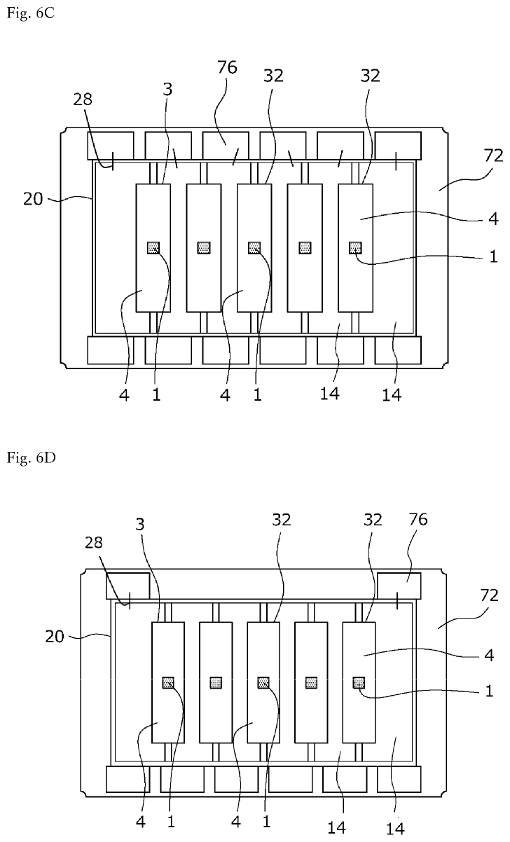

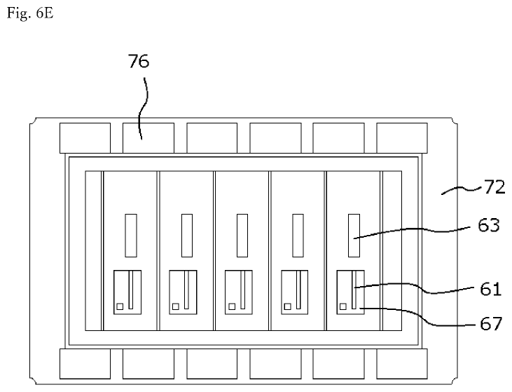

6E is a schematic plan view illustrating the arrangement of a semiconductor laser element and the like in the light-emitting device of FIG. 6A.

### DETAILED DESCRIPTION

Embodiments for carrying out the present invention are described below with reference to the drawings. The following embodiments are for embodying the technical concept of the present invention, and are not intended to limit the present invention. Note that, size, positional relationship, or the like of members illustrated in the drawings can be exaggerated for clarity of description.

In the drawings, arrows 1st and 2nd mean a first direction and a second direction, respectively.

### First Embodiment

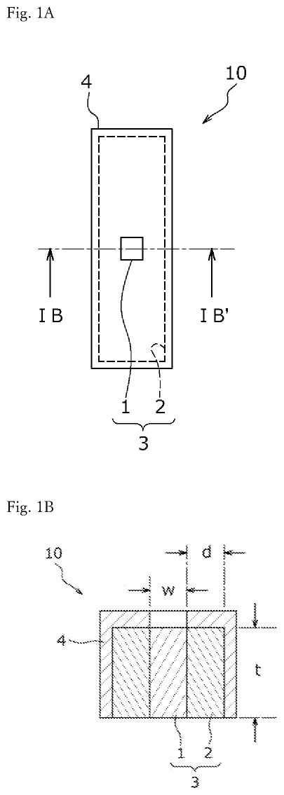

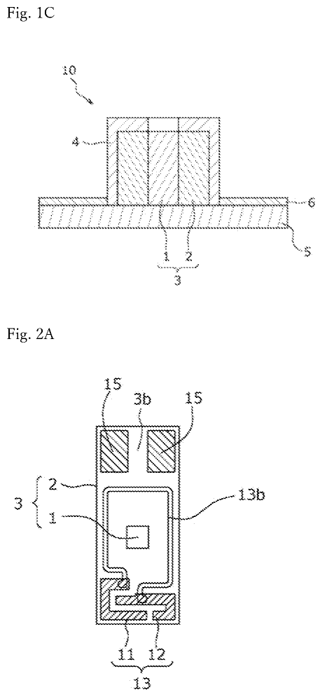

An optical member 10 according to the first embodiment includes a wavelength conversion member 3 and the light shielding film 4 as illustrated in FIGS. 1A and 1B. The wavelength conversion member 3 includes a wavelength conversion portion 1 and a ceramic portion 2. The ceramic portion 2 surrounds the lateral surface of the wavelength conversion portion 1. The light shielding film 4 is provided on the outer lateral surface of the wavelength conversion member 3.

Note that in the optical member 10 according to the first embodiment, the ceramic portion 2 may include a light reflecting portion with its material not limited to being ceramic. The light reflecting portion is provided with a void at or near the inner lateral surface surrounding the lateral surface of the wavelength conversion portion 1. Alternatively, the light reflecting portion may have a reflective structure, and the distance between a lateral surface of the wavelength conversion portion 1 and an outer lateral surface of the light reflecting portion closest to the lateral surface of the wavelength conversion portion 1 may be in a range from 0.3 mm to 30 mm.

The optical member 10 according to the first embodiment includes the wavelength conversion member 3 and the light shielding film 4, and the light shielding film 4 is provided on only the upper surface of the wavelength conversion member 3 and the outer lateral surface of the wavelength conversion member 3. The wavelength conversion member 3 is preferably made of ceramic, but is not limited to being made of ceramic. In the wavelength conversion member 3, the ceramic portion 2 may be a surrounding portion not limited to being ceramic. The surrounding portion surrounds the wavelength conversion portion 1. The surrounding portion may not have light reflectivity and may be provided with a void.

The optical member 10 may further include a light-transmitting member 5, as illustrated in FIG. 1C, for example. The wavelength conversion member 3 is disposed on the upper surface of the light-transmitting member 5.

By the optical member being configured as such, leakage of the light incident on the wavelength conversion portion from the lateral surface of the ceramic portion can be reduced or prevented. In a case in which the thickness of the ceramic portion covering the lateral surface of the wavelength conversion portion is thin, light may leak from the lateral surface of the ceramic portion. However, in such a case, using a light shielding film can effectively prevent light leakage, as well as allowing the optical member to be made more compact.

Hereinafter, the wavelength conversion member 3 including the wavelength conversion portion 1 and the ceramic portion 2 will be described. Regarding the matters described, bar any clear inconsistency, the description of the ceramic portion 2 also applies to the light reflecting portion and the surrounding portion. In the case of a clear inconsistency, for example, a note that “the ceramic portion 2 may not have a reflective structure” may be added with respect to a light reflecting portion with a reflective structure.

### Wavelength Conversion Member 3

The wavelength conversion member 3 includes the wavelength conversion portion 1 and the ceramic portion 2 surrounding the lateral surface of the wavelength conversion portion 1. The wavelength conversion portion 1 and the ceramic portion 2 are preferably integrally formed.

### Wavelength Conversion Portion 1

The wavelength conversion portion 1 is a member that converts incident light into light of a different wavelength. The wavelength conversion portion 1 may be formed using various materials such as inorganic materials, organic materials, and the like. The wavelength conversion portion 1 is preferably formed of an inorganic material due to its tendency to not degrade due to heat generated during light irradiation. Examples of the inorganic material include ceramic and the like.

The wavelength conversion portion 1 includes a phosphor, for example. For example, the wavelength conversion portion 1 may include ceramic as the main material, include a phosphor, or be made of a single-crystal phosphor. Here, the main material refers to the material with the greatest proportion from among all materials that form the wavelength conversion portion.

In a case in which ceramic is used in the wavelength conversion portion 1, sintered material of a phosphor and a light-transmitting material such as aluminum oxide (Al₂O₃, melting point: in a range from approximately 1900° C. to 2100° C.) may be used, for example. A specific example includes a composite ceramic of aluminum oxide containing a YAG phosphor. For example, the content of the phosphor may be in a range from 0.05 volume % to 50 volume % with respect to the total volume of the ceramic. A ceramic sintered body substantially made of only a phosphor may be used. In a case in which a phosphor single-crystal is used as the wavelength conversion portion 1, a wavelength conversion portion with less light scattering compared to a case in which ceramic is used can be obtained. With such a configuration, a member with a higher heat resistance compared to a member made using resin including a phosphor is obtained, allowing it to be used for a relatively long time in laser beam irradiation.

A phosphor known in the art can be used as the phosphor. Examples include an yttrium aluminum garnet (YAG) phosphor activated with cerium, a lutetium aluminum garnet (LAG) phosphor activated with cerium, a silicate phosphor activated with europium, and the like. In particular, a YAG phosphor is preferably used due to its good heat resistance. Two or more types of phosphor may be included in the wavelength conversion portion 1.

The shape of the wavelength conversion portion 1 in a plan view can be a variety of shapes, such as a circular shape or elliptical shape, a polygonal shape such as a triangle or a quadrilateral, or the like. Of these, the wavelength conversion portion 1 is preferably a quadrilateral in a plan view. The wavelength conversion portion 1 includes an upper surface, lateral surfaces, and a lower surface, for example. The wavelength conversion portion 1 may be thick or thin in some sections. Preferably, the wavelength conversion portion 1 has a rectangular parallelepiped-shaped, flat plate-like shape with a uniform thickness. Taking into account strength, the thickness of the wavelength conversion portion 1 (t in FIG. 1B) is 0.2 mm or greater. The thickness is preferably 1 mm or less in order to suppress the increase in the cost of manufacturing and the height of the wavelength conversion member 3, and to ensure that the degree of wavelength conversion is appropriate. The upper surface, the lateral surfaces, and the lower surface of the wavelength conversion portion 1 may not be planar, but are preferably planar. The upper and lower surfaces of the wavelength conversion portion 1 are preferably parallel with one another. The lateral surfaces of the wavelength conversion portion 1 may be perpendicular to the upper surface of the wavelength conversion portion 1, or may be inclined so as to expand inward or inward, or may have a curved surface. In the wavelength conversion portion 1, one side or a diameter (w in FIG. 1B) of the planar form is in a range from 0.25 mm to 2 mm, for example.

### Ceramic Portion 2

The ceramic portion 2 surrounds the lateral surface of the wavelength conversion portion 1. In this case, the ceramic portion 2 preferably surrounds all of the height direction of the lateral surface of the wavelength conversion portion 1. The ceramic portion 2 preferably surrounds the entire outer periphery of the wavelength conversion portion 1. In other words, the ceramic portion 2 may have a shape including a through hole in the central portion, with the wavelength conversion portion 1 housed in the through hole. In this case, the ceramic portion 2 is preferably integrally formed in contact with the wavelength conversion portion 1.

The external shape of the ceramic portion 2 in a plan view can be a variety of shapes, such as a circular shape or elliptical shape, a polygonal shape such as a triangle or a quadrilateral, or the like. Of these, the ceramic portion 2 preferably has a quadrangular external shape in a plan view. The ceramic portion 2 preferably has a rectangular parallelepiped-shaped flat plate-like shape with an upper surface, lateral surfaces, and a lower surface. The upper surface and the outer lateral surfaces of the ceramic portion 2 may not be planar, but the lower surface is preferably planar. This makes it easy to join the lower surface of the ceramic portion 2 to other members such as the package described below. Regarding the size of the ceramic portion 2, one side or a diameter of the planar form is in a range from 1 mm to 100 mm, for example. In FIGS. 1A and 1B, the shape is a rectangular parallelepiped, with sides of dimensions such as 1.5 mm×5.0 mm. The distance (d in FIG. 1B) between the outer edge (outer lateral surface) of the wavelength conversion portion 1 and the outer edge (outer lateral surface) of the ceramic portion 2 closest thereto, i.e., the outer edge of the wavelength conversion member 3, is in a range from 0.25 mm to 2.0 mm. The distance d, for example, is in a range from 1/10 times to 1/1 times of the side or diameter (w in FIG. 1B) of the planar form of the wavelength conversion portion 1. Taking into account strength, the thickness of the ceramic portion 2 (tin FIG. 1B) is 0.2 mm or greater, for example. The thickness of the ceramic portion 2 is preferably 1 mm or less in order to suppress an increase in thickness. The ceramic portion 2 may be thick or thin in some sections, but preferably has a uniform thickness.

As illustrated in FIG. 1B, the ceramic portion 2 may be flush with the upper surface and/or the lower surface of the wavelength conversion portion 1 or may include a recess portion recessed below the upper surface and/or the lower surface of the wavelength conversion portion 1 or a protrusion portion protruding from the upper surface and/or the lower surface of the wavelength conversion portion 1. Of these, as illustrated in FIG. 1B, the ceramic portion 2 is preferably flush with at least the lower surface of the wavelength conversion portion 1 and is more preferably flush with both the lower surface and the upper surface.

The ceramic portion 2 preferably has a reflectivity for reflecting the light emitted from the wavelength conversion portion 1. For example, the ceramic portion 2 is a porous member including a void or voids. The ceramic portion 2 may have a reflectivity for reflecting the light emitted from the wavelength conversion portion 1 because of this void. The void is preferably provided in the vicinity of a region where light is to be reflected. Voids do not need to be uniformly formed in the ceramic portion 2. The voids can be disposed in a region of an area ranging from 50 μm to 300 μm from the inner lateral surface of the ceramic portion 2 surrounding the lateral surfaces of the wavelength conversion portion 1. The ceramic portion 2 may include portions where the density of the voids is different. By adjusting the density of the voids, light reflectivity can be controlled. The density of the voids can be adjusted by changing the conditions of the sintering of the ceramic material, as described below. The voids can be confirmed, for example, by observing the cross-section of the observation target with a scanning electron microscope (SEM).

The ceramic portion 2, as long as ceramic is included, can be formed of a metal, a different ceramic, a resin, a glass, or a composite material including one or more of these. The ceramic portion 2 may include a material that reflects the light emitted by the semiconductor laser element described below and reflects the fluorescence emitted by the phosphor in the wavelength conversion portion 1. The main material of the ceramic may include aluminum oxide, aluminum nitride, yttrium oxide, silicon nitride, silicon carbide, and the like, and may be a composite ceramic of aluminum oxide (alumina) and yttrium oxide or the like.

In a case in which the ceramic portion 2 includes portions of different void density, the portion with the greater void density is preferably disposed at the portion closer to the lateral surface of the wavelength conversion portion and the portion with the less void density is preferably disposed at the portion distanced from the lateral surface of the wavelength conversion portion, i.e., on the outer side of the portion with the greater void density. In other words, the portion with the higher porosity is preferably disposed at the portion closer to the lateral surface of the wavelength conversion portion, and the portion with the lower porosity is preferably disposed on the outer side thereof. With such an arrangement, light from the wavelength conversion portion 1 scatters inside the portion with the greater void density at the lateral surface of the wavelength conversion portion 1, making the effect of suppressing light transmissivity significant.

The wavelength conversion member 3 configured as such can be manufactured by the method described in JP 2017-149929, JP 2019-9406, and the like or a method based on these methods. In this case, only one wavelength conversion portion 1 may be formed, a plurality of the wavelength conversion portions 1 may be formed, or, after a plurality of the wavelength conversion portions 1 are formed, the ceramic portion 2 may be cut into sections corresponding to one wavelength conversion portion 1 or a plurality of the wavelength conversion portions 1.

(a) For example, the wavelength conversion portion 1 including an upper surface, a lower surface, and lateral surfaces is prepared. A plurality of the wavelength conversion portions 1 may be prepared. The wavelength conversion portion 1 is a sintered body including ceramic and a phosphor, for example. The wavelength conversion portion at this point in time may be an unsintered formed article. Then, a composite formed article including powder made of an inorganic material is formed in contact with the wavelength conversion portion 1 and surrounding the periphery thereof, i.e., surrounding the wavelength conversion portion 1 from the sides, below, and/or above. Then, by sintering the composite formed article, the wavelength conversion member 3 including the wavelength conversion portion 1 and the ceramic portion 2 surrounding the wavelength conversion portion 1 can be formed. (b) Alternatively, a ceramic portion 2 with an uneven surface is prepared. The ceramic portion 2 is, for example, a sintered body including ceramic. The ceramic portion at this point in time may be an unsintered formed article. A powder including inorganic material and a phosphor is disposed in the recess portion of the ceramic portion 2 to form a composite formed article. Then, by sintering the composite formed article, a first wavelength conversion member 3 including the wavelength conversion portion 1 and the ceramic portion 2 surrounding the wavelength conversion portion 1 can be formed.

According to such a manufacturing method, the wavelength conversion portion 1 and the ceramic portion 2 can be formed as sintered bodies or preferably an integrally formed sintered body. The integrally formed sintered body here refers to the sintered bodies (ceramic) being integrally formed without using an adhesive formed by integrally sintering them. For sintering, for example, a spark plasma sintering method (SPS method), a hot press sintering method (HP method), a pressureless sintering method, a gas pressure sintering method, and the like can be used.

The lateral surfaces of the wavelength conversion portion 1 are surrounded by the ceramic portion 2, but the upper surface and/or the lower surface of the wavelength conversion portion 1 may also be covered by the ceramic portion 2. In this case, the upper surface and the lower surface of the wavelength conversion portion 1 are exposed from the ceramic portion 2 by machining, finishing, or the like. Here, machining, finishing, or the like is preferably performed to expose the wavelength conversion portion 1 from the ceramic portion 2 by making the upper surface of the wavelength conversion portion 1 and the upper surface of the ceramic portion 2 flush with one another and/or making the lower surface of the wavelength conversion portion 1 and the lower surface of the ceramic portion 2 flush with one another.

The wavelength conversion portion 1 and the ceramic portion 2 may differ in terms of removal rate when machining, finishing, or the like in a case in which the content ratio or the like of material and voids is different. In a case in which the wavelength conversion portion 1 has a faster removal rate than the upper surface and/or the lower surface of the ceramic portion 2, the upper surface and/or the lower surface of the wavelength conversion portion 1 is formed with a recess portion recessed inward from the upper surface and/or the lower surface of the ceramic portion 2. On the other hand, in a case in which the wavelength conversion portion 1 has a slower removal rate than the upper surface and/or the lower surface of the ceramic portion 2, the upper surface and/or the lower surface of the wavelength conversion portion 1 is formed with a protrusion portion protruding outward from the upper surface and/or the lower surface of the ceramic portion 2. The recess portion and the protrusion portion in these cases have a depth or height ranging from 0.1 μm to 5 μm and preferably have a depth or height ranging from 0.1 μm to 1 μm.

The wavelength conversion portion 1 and the ceramic portion 2 are the same ceramic sintered body as described above, but it is preferable that the wavelength conversion portion 1 and the ceramic portion 2 satisfy at least one or all of the following size relationships. (1) The wavelength conversion portion 1 has greater density than the ceramic portion 2. (2) The wavelength conversion portion 1 has a less void content ratio than the ceramic portion 2. (3) The wavelength conversion portion 1 has greater strength than the ceramic portion 2. In order to achieve such a size relationship, sintering conditions including the temperature, pressure, and heat treatment time can be adjusted. For example, if the pressure is low, voids tend to form in the sintered body, increasing the void content ratio (referred to herein as the porosity of the sintered body). If sintering is performed for a short time at high temperatures, the particle size is decreased, lowering the average particle size. In order to make the processing conditions different between the wavelength conversion portion 1 and the ceramic portion 2 in this manner, either the wavelength conversion portion 1 or the ceramic portion 2 is preferably sintered first and then the other.

The wavelength conversion portion 1 can be formed such that the void content ratio is greater than 0% and 5% or less, for example. The ceramic portion 2 can be formed such that the void content ratio is in a range from 5% to 20%. A void is provided at or near the inner lateral surface of the ceramic portion 2 surrounding the wavelength conversion portion 1. Specifically, the wavelength conversion portion 1 has a less void content ratio than the ceramic portion 2 of 5% or greater. The contact surface between the wavelength conversion portion 1 and the ceramic portion 2, i.e., the region at or near the lateral surface of the wavelength conversion portion 1, has a less void content ratio than the region at or near the inner lateral surface of the ceramic portion 2 of 5% or greater.

The void content ratio between the wavelength conversion portion 1 and the ceramic portion 2 can be measured, for example, by the Archimedes method. The void content ratio may be determined from an SEM image of the cross section.

### Light Shielding Film 4

The light shielding film 4 is provided on the outer lateral surface of the wavelength conversion member 3. The light shielding film 4 is also provided on the upper surface of the ceramic portion 2 of the wavelength conversion member 3. The light shielding film 4 is provided covering, of the upper surface of the wavelength conversion member 3, the upper surface of the ceramic portion 2. That is, the light shielding film 4 is provided on the upper surface and the outer lateral surfaces of the ceramic portion 2. In this case, the outer lateral surface is preferably completely surrounded in the height direction and the entire periphery of the outer lateral surface is also preferably surrounded. Accordingly, light emitted from the outer lateral surface can be suppressed. The light shielding film 4 is not provided at least at a portion of the upper surface of the wavelength conversion portion 1. The light shielding film 4 is preferably not provided entirely on of the upper surface of the wavelength conversion portion 1. In other words, the light shielding film 4 is preferably disposed on the upper surface of the wavelength conversion member 3 only on the upper surface of the ceramic portion 2. The light shielding film 4 more preferably covers the entire upper surface of the wavelength conversion member 3 other than the upper surface of the wavelength conversion portion 1. In other words, the light shielding film 4 preferably entirely covers the upper surface of the ceramic portion 2. In this case, the entire upper surface of the wavelength conversion portion 1 is preferably exposed from the light shielding film 4, but the light shielding film 4 may cover a portion of the upper surface of the wavelength conversion portion. In other words, how much the wavelength conversion portion 1 is exposed from the light shielding film 4 is preferably in a range from 50% to 100% of the flat surface area of the upper surface of the wavelength conversion portion 1 and more preferably is 100% of the flat surface area of the upper surface of the wavelength conversion portion 1. By disposing the light shielding film 4 as such, light from the upper surface and/or the lateral surfaces of the ceramic portion 2 can be shielded, allowing leakage of light incident on the wavelength conversion portion 1 to be effectively reduced or prevented. Furthermore, light from the outside can be blocked from being reflected at the upper surface of the ceramic portion 2.

The light shielding film 4 has light shielding properties with respect to the light emitted from the wavelength conversion portion 1. The light from the wavelength conversion portion 1 includes excitation light and fluorescence emitted by the phosphor by excitation light. Any material with a transmittance with respect to this light of 20% or less, 15% or less, or 10% or less can be used as the light shielding film 4.

A metal can be used as the material of the light shielding film 4, for example. By using a material such as these, a portion of the material forming the first wavelength conversion member 3 can be selectively removed via laser processing or the like. The light shielding film 4 is preferably formed from a metal film. A metal film has higher resistance to heat than resin and thus is more suitable in cases in which a laser element is used as the excitation light source.

Examples of the metal film forming the light shielding film 4 include a single layer film or a multilayer film of a metal such as aluminum, titanium, nickel, or the like; a noble metal such as platinum; or a metal oxide or alloy thereof. When a noble metal is used, the light shielding film 4 can be formed with good accuracy. Since adhesion between noble metals and ceramic is not good, the light shielding film 4 can be formed only on, of the wavelength conversion member 3, the surface of the ceramic portion 2 using an anchor effect utilizing the unevenness of the surface due to the formation of voids in the ceramic portion 2. A specific example includes a multilayer film of Pt/Ru/RuO₂ or the like. These metal films can be formed by sputtering, vacuum vapor deposition, or the like. The light shielding film 4 is formed with a thickness ranging from 0.1 μm to 10 μm and preferably has a thickness ranging from 0.5 μm to 1 μm. Accordingly, light shielding properties can be reliably ensured.

In order to dispose the light shielding film 4 on the outer lateral surface of the wavelength conversion member 3, the metal film forming the light shielding film 4 may be formed on the entire surface of the wavelength conversion member 3, then a portion of the light shielding film 4 may be removed, and the wavelength conversion portion 1 may be exposed from the light shielding film 4. The light shielding film 4 on the wavelength conversion portion 1 can be removed by using the weakness of adhesion described above, but can also be removed by laser processing.

### Light-Transmitting Member 5

As illustrated in FIG. 1C, the wavelength conversion member 3 is disposed on the upper surface of the light-transmitting member 5. One or a plurality of the wavelength conversion members 3 are disposed on the upper surface of the light-transmitting member 5.

For example, the light-transmitting member 5 is a plate-like member including a lower surface, an upper surface, and lateral surfaces. The light-transmitting member 5 preferably includes a flat upper surface on which the wavelength conversion portion 1 is placed. Such a shape makes it easy to join with the wavelength conversion portion 1 and allows a thermal connection to be made in a relatively wide area. This allows the heat of the wavelength conversion portion 1 to be efficiently released to the light-transmitting member 5. The lower surface and the lateral surfaces of the light-transmitting member 5 may not be flat.

The light-transmitting member 5 can be formed from sapphire, quartz, silicon carbide, glass, or the like. The light-transmitting member 5 can include a light-transmitting region through which light transmits from the upper surface to the lower surface. This allows the excitation light to enter from the lower surface of the light-transmitting member 5 and reach the wavelength conversion portion 1. Here, “light transmissivity” means that the light transmittance is 80% or greater with respect to the incident light (excitation light). Of these, a light-transmitting sapphire is preferably used for the light-transmitting member 5. Sapphire has a high transmittance and a high strength, and thus is a suitable material for forming the light-transmitting member 5.

The light-transmitting member 5 may have the same planar shape as the wavelength conversion member 3, or may have a different planar shape. The light-transmitting member 5 may have the same size as the wavelength conversion member 3 in plan view or may have a different size. For example, the light-transmitting member 5 may be greater than the wavelength conversion member 3 in a plan view. In this case, a light shielding member 6 may be disposed around a region where the wavelength conversion member 3 is disposed on the upper surface of the light-transmitting member 5. The light shielding member 6 can be formed of a single layer film or a multilayer film of a metal such as aluminum, titanium, nickel, or the like or a metal oxide or alloy thereof. A specific example includes a multilayer film of Ti/Pt/Au or the like. The metal of the light shielding member 6 provided on the surface of the light-transmitting member 5 differs from the metal of the light shielding film 4 provided on the surface of the wavelength conversion member 3.

The light shielding member 6 may partially overlap with the wavelength conversion member 3 (ceramic portion 2) as long as the light shielding member 6 does not overlap with the wavelength conversion portion 1 on the upper surface of the light-transmitting member 5. The light shielding member 6 may be disposed on the lower surface of the light-transmitting member 5. In a case in which light enters from the lower surface side of the light-transmitting member 5, the light shielding member 6 being provided on the upper surface of the light-transmitting member 5 makes it easier to effectively shield the light together with the light shielding film 4.

### Wiring Layer

The optical member 10 may include a first wiring layer provided on the lower surface of the wavelength conversion member 3 and a second wiring layer provided on the upper surface of the light-transmitting member 5. The second wiring layer is disposed at a position that is joined to the first wiring layer.

The first wiring layer and the second wiring layer together form a safety wiring line, for example. In other words, as described below, in a case in which the optical member 10 is used in a light-emitting device using a semiconductor laser element, the first wiring layer and the second wiring layer are provided for the purpose of preventing a laser beam emitted from the semiconductor laser element being directly emitted outside of the package of the light-emitting device or the module using the package. In other words, in a case in which cracking or breaking occurs in the wavelength conversion portion 1 of the optical member, the laser beam emitted to the wavelength conversion member 3 includes light that does not pass through the wavelength conversion portion 1 and is directly emitted outside of the package. However, the first wiring layer and the second wiring layer correspond to a wiring line that may detect cracks or break in the wavelength conversion portion 1 to prevent such a situation occurring.

The first wiring layer and the second wiring layer are preferably formed from a metal film and/or a light-transmitting conductive film. Examples of the metal film include a single layer film or a multilayer film of a metal such as Au, Sn, Ag, Cu, Ni, Rh, Pd, Al, W, Pt, and Ti or an alloy thereof. Examples of the light-transmitting conductive film include those having light transmittance of, for example, 60% or greater, 70% or greater, 75% or greater, or 80% or greater with respect to visible light (visible region). Examples of the light-transmitting conductive film include films of an oxide including at least one type selected from Zn, In, Sn, Mg, and specifically, ZnO, In₂O₃, SnO₂, Indium Tin Oxide (ITO), Indium Zinc Oxide (IZO), Gallium-doped Zinc Oxide (GZO), or the like. The thickness of the light-emitting conductive film can be discretionarily set.

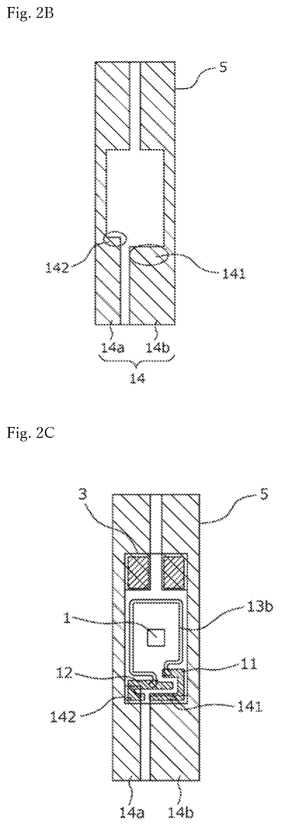

As illustrated in FIG. 2A, a first wiring layer 13 in the wavelength conversion member 3 can have a shape including, on a lower surface 3b of the wavelength conversion member 3, i.e., the lower surface of the ceramic portion 2, a first join portion 11 disposed on one end side of the ceramic portion 2, a connection portion 13b extending from the first join portion 11 and surrounding the outer periphery of the wavelength conversion portion 1, and a second join portion 12 extending from the connection portion 13b to be separated from the first join portion 11 on one end side. The first wiring layer 13 preferably extends in a thin linear shape and has a width ranging from 1/10 times to ⅕ times of the side or diameter of the wavelength conversion portion 1, for example. In order to prevent inclination when joining the wavelength conversion member 3 and the light-transmitting member 5 described below, it is preferable to dispose a third join portion 15 on the lower surface of the ceramic portion 2 on the opposite side to the first join portion 11 (upper side in FIG. 2A).

As illustrated in FIG. 2B, two second wiring layers 14 in the light-transmitting member 5 include two second wiring layers 14a and 14b including a first portion 141 and a second portion 142 that surround the wavelength conversion member 3 and at a position overlapping the wavelength conversion member 3, in other words, that extend to a position where the wavelength conversion member 3 is joined to the first join portion 11 and the second join portion 12 of the first wiring layer. The second wiring layers 14 can also function as the light shielding member 6. That is, instead of providing the light shielding member 6 separately from the second wiring layer 14, the second wiring layer 14 can also function as the light shielding member 6. In this case, the light shielding member 6 may not be provided separately.

By disposing the wavelength conversion member 3 on the light-transmitting member 5 in this manner, as illustrated in FIG. 2C, the first join portion 11 of the first wiring layer 13 is joined to the first portion 141, which is an extended portion of the second wiring layer 14b, and the second join portion 12 of the first wiring layer 13 is joined to the second portion 142, which is an extended portion of the second wiring layer 14a.

### Second Embodiment

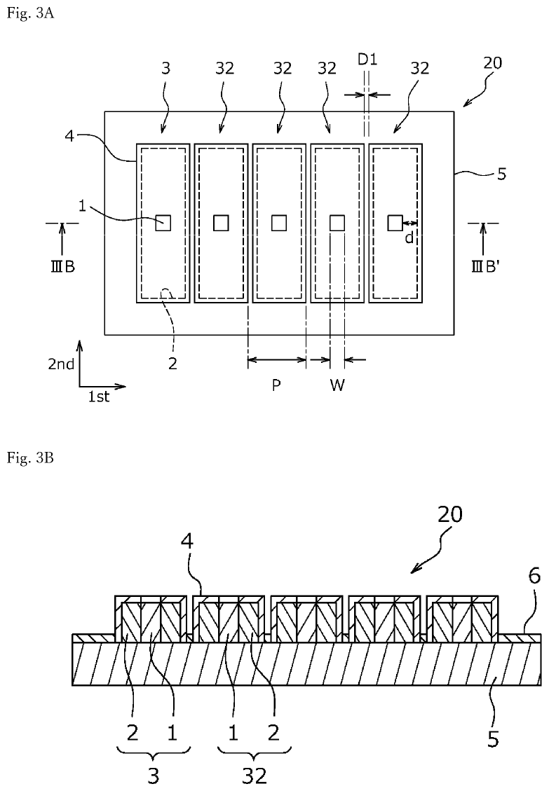

An optical member 20 according to the second embodiment includes a plurality of the wavelength conversion members 3 as illustrated in FIGS. 3A and 3B. That is, in addition to the single wavelength conversion member 3 (also referred to as the first wavelength conversion member 3), the optical member 20 further includes one or a plurality of wavelength conversion members 3 (also referred to as the second wavelength conversion member 32) including the wavelength conversion portion 1 and the ceramic portion 2 surrounding the lateral surfaces of the wavelength conversion portion 1. Here, “plurality” means two or more and can be a number set, depending on the performance of the light-emitting device that optical member is used in, for example, 30 or less or 20 or less. In FIGS. 3A and 3B, the optical member 20 includes one first wavelength conversion member 3 and four second wavelength conversion members 32.

The wavelength conversion portion 1 and the ceramic portion 2 constituting the second wavelength conversion member 32 can be configured in a similar manner to the wavelength conversion portion 1 and the ceramic portion 2 constituting the first wavelength conversion member 3. The type and/or amount of the phosphor included in the plurality of wavelength conversion portions 1 of the first wavelength conversion member 3 and the second wavelength conversion members 32 may be the same or one or all of them may be different from one another. In addition, in the first wavelength conversion member 3 and the second wavelength conversion members 32, in a plan view, the plurality of wavelength conversion portions 1 and the plurality of ceramic portions 2 preferably have the same size, but one or all of them may be different from one another.

The first wavelength conversion member 3 and the one or the plurality of second wavelength conversion members 32 configured as such are disposed on the upper surface of the light-transmitting member 5. In this case, the first wavelength conversion member 3 and the one or the plurality of second wavelength conversion members 32 are disposed side by side, i.e., in a row. The ceramic portions 2 of the wavelength conversion members disposed adjacent to each other in the first wavelength conversion member 3 and the one or the plurality of second wavelength conversion members 32 are preferably separated from one another.

Specifically, the first wavelength conversion member 3 and the one or the plurality of second wavelength conversion members 32 are aligned in the first direction. The first wavelength conversion member 3 and the one or the plurality of second wavelength conversion members 32 are disposed in a linear manner. The wavelength conversion portion 1 in the first wavelength conversion member 3 and the wavelength conversion portion 1 in each second wavelength conversion member 32 are arranged linearly in the first direction. The first wavelength conversion member 3 and the one or the plurality of second wavelength conversion members 32 are quadrangular in a plan view, and the sides adjacent in the first direction are disposed parallel to each other. In the wavelength conversion portions 1 of the first wavelength conversion member 3 and the one or the plurality of second wavelength conversion members 32, for example, an interval or a pitch P in the first direction is in a range from 2 times to 5 times a width W in the first direction of the wavelength conversion portion 1. Here, the pitch P refers to the width of each cycle of the first wavelength conversion member 3 and the second wavelength conversion member 32. Accordingly, the plurality of wavelength conversion portions 1 can be disposed close together. A distance D1 in the first direction between adjacent wavelength conversion members 3 is in a range from ⅕ times to 1/1 times the width W in the first direction of the wavelength conversion portion 1, for example. Accordingly, the plurality of wavelength conversion members 3 can be disposed close together.

The light shielding member 6 may be disposed on the upper surface of the light-transmitting member 5 between at least the adjacent wavelength conversion members 3.

### Wiring Layer

The optical member 20 is preferably provided with the first wiring layer on the lower surface of each one of the first wavelength conversion member 3 and the one or the plurality of second wavelength conversion members 32. A plurality of second wiring layers joined to the first wiring layer are preferably provided on the upper surface of the light-transmitting member. The plurality of second wiring layers are preferably provided side by side in the first direction so as to conform to the arrangement of the first wavelength conversion member 3 and the second wavelength conversion members 32. The first wiring layer of each wavelength conversion member 3 and the plurality of second wiring layers are, for example, electrically connected in series. The connection may be electrical and parallel or a combination of in series and parallel connections may be used. In order to detect the occurrence of cracks and the like in any one of the plurality of wavelength conversion members 3, it is sufficient to have an electrical connection in series. On the other hand, in a case of individual detection, the connection is preferably electrical and parallel.

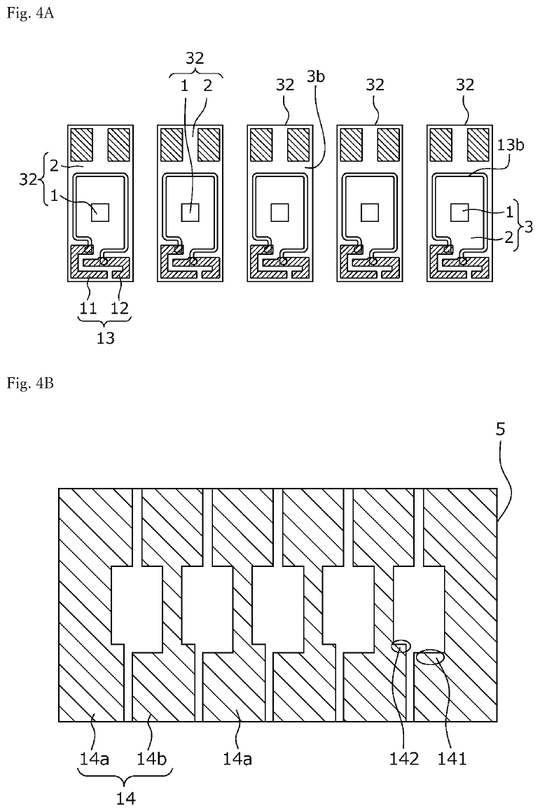

As illustrated in FIG. 4A, the first wiring layer 13 in the first wavelength conversion member 3 can have a shape including, on a lower surface 3b of the first wavelength conversion member 3, i.e., the lower surface of the ceramic portion 2, a first join portion 11 disposed on one end side of the ceramic portion 2, a connection portion 13b extending from the first join portion 11 and surrounding the outer periphery of the wavelength conversion portion 1, and a second join portion 12 extending from the connection portion 13b to be separated from the first join portion 11 on one end side. As in the first wavelength conversion member 3, the second wavelength conversion member 32 includes the first wiring layer 13 including the first join portion 11 and the second join portion 12.

As illustrated in FIG. 4B, the two second wiring layers 14 in the light-transmitting member 5 surround the wavelength conversion members 3. Each of the adjacent wavelength conversion members 3 is joined and electrically connected to the second wiring layer 14 sandwiched between adjacent wavelength conversion members 3. The first join portion 11 of the first wiring layer 13 of one wavelength conversion member 3 of the adjacent wavelength conversion members 3 is joined to the first portion 141 of the corresponding second wiring layer 14, and the second join portion 12 of the first wiring layer 13 of the other wavelength conversion member 3 is joined to the second portion 142 of the corresponding second wiring layer 14.

The two second wiring layers 14 surround the first wavelength conversion member 3, the two second wiring layers 14 surround the second wavelength conversion member 32 disposed adjacent to the first wavelength conversion member 3, and one of the former two second wiring layers 14 and one of the latter two second wiring layers 14 are the same second wiring layer 14. In the illustrated optical member 20, the first join portion 11 of the first wavelength conversion member 3 is joined to the first portion 141 of the second wiring layer 14b and the second join portion 12 of the second wavelength conversion member 32 is joined to the second portion 142 of the second wiring layer 14b.

With such a configuration, in a case in which cracking or breaking occurs in the wavelength conversion member 3, because the first wiring layer 13 or the like disposed in the wavelength conversion member 3 breaks, this breakage can be detected and power can stop being sent to the semiconductor laser element.

The shape and the like of the first join portion 11, the second join portion 12, the first wiring layer 13, the connection portion 13b, the second wiring layers 14, and the like can be discretionarily set in a manner such that the joining described above and the functions described above can be achieved.

### Third Embodiment

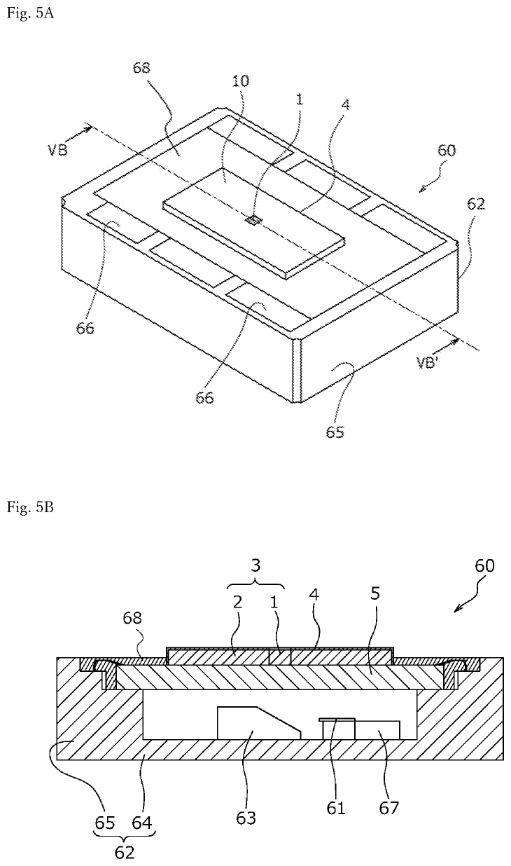

As illustrated in FIGS. 5A and 5B, a light-emitting device 60 according to the third embodiment includes a package 62, the optical member 10 described above, and a semiconductor laser element 61.

The light-emitting device 60 is further preferably provided with a light reflecting member 63.

With a light-emitting device configured as such, leakage light from the optical member 10 after the light emitted from the semiconductor laser element 61 is incident on the optical member 10 can be effectively reduced or prevented.

### Package 62

The package 62 includes a base portion 64 and a wall portion 65 extending from the base portion 64. The wall portion 65 surrounds the base portion 64 and extends in the thickness direction of the base portion 64 and together with the base portion 64, and forms a recessed or housing-like package 62. The wall portion 65 may include a step within the recess or within the housing of the package 62. In the base portion 64 and/or the wall portion 65, electrodes 66 or the like for supplying current to the semiconductor laser element are disposed.

The package 62 can be formed primarily from a ceramic such as aluminum oxide, aluminum nitride, silicon nitride, silicon carbide, and the like, a metal such as copper, or another metal with insulating properties. The package 62 can have a variety of shapes, such as a quadrangular shape in a top view.

### Optical Member 10

The optical member 10 is disposed on the wall portion 65 on the opposite side to the base portion 64 and defines a recess or housing-like space together with the base portion 64 and the wall portion 65 of the package 62. The optical member 10 is fixed to the package 62, specifically the wall portion 65, via a metal bonding layer, for example. Examples of the metal bonding layer include Sn—Bi-based, Sn—Cu-based, or Sn—Ag-based solders, eutectic alloys such as alloys having Au and Sn as a main component, alloys having Au and Si as a main component, or alloys having Au and Ge as a main component, waxes made from low melting point metals, adhesives combining these, and the like.

By joining the light-transmitting member 5 to the wall portion 65, a closed space in which the semiconductor laser element 61 is disposed can be formed. In other words, the light-transmitting member 5 of the optical member 10 functions as a lid of the package 62. The closed space is formed in a hermetically sealed state. By being hermetically sealed, dust collection of organic matter and the like on the emitting end surface of the light of the semiconductor laser element 61 can be suppressed.

### Semiconductor Laser Element 61

The semiconductor laser element 61 is disposed in the space defined by the package 62 and the optical member 10. The semiconductor laser element 61 may be disposed directly on the base portion 64 of the package 62, but is preferably disposed on a submount 67. Examples of the submount 67 include submounts formed using SiC, AlN, or the like as the main material. The semiconductor laser element 61 can be mounted on the submount 67 using an AuSn eutectic solder or the like.

The semiconductor laser element 61 is preferably mounted so that a laser beam emitted from the semiconductor laser element 61 travels in a substantially parallel direction to the surface of the base portion 64. Substantially parallel here means that an inclination of approximately ±10° is acceptable. The semiconductor laser element 61 may emit a laser beam to the optical member 10.

The light (laser beam) emitted from the semiconductor laser element 61 spreads and forms a far field pattern (FFP) of an elliptical shape in a plane parallel to the emitting end surface of the light, for example. The semiconductor laser element 61 may employ, for example, a semiconductor laser element that emits blue light having an emission peak wavelength ranging from 430 nm to 480 nm. Examples of such a semiconductor laser element include semiconductor laser elements including a nitride semiconductor, such as GaN, InGaN, AlGaN, and the like.

### Light Reflecting Member 63

The light reflecting member 63 is used to guide the light emitted from the semiconductor laser element 61 toward the wavelength conversion portion 1 of the optical member 10. Thus, the light reflecting member 63 is preferably disposed on the base portion 64 of the package 62. The light reflecting member 63 preferably faces the end face where the laser beam of the semiconductor laser element 61 is emitted. Accordingly, the laser beam emitted from the semiconductor laser element 61 is emitted to the light reflecting member 63 and reflects at the light reflecting member 63 in the direction of the optical member 10 fixed on the upper surface side of the package 62, causing excitation light to be emitted to the wavelength conversion portion 1.

For the light reflecting member 63, a triangular prism or a frustum shaped member provided with a reflection film on an inclined surface of the body portion made of glass, Si, or the like can be used. As the reflection film, a single layer or a multilayer dielectric film or a metal film can be used.

A protecting element (for example, a Zener diode formed from Si), a temperature measuring element, the electrodes 66, wiring line, and the like may be disposed in the package 62 or on the upper surface of the package 62, for preventing excessive current flowing to the semiconductor laser element causing it to be damaged.

A resin member 68 may be disposed on the upper surface of the package 62 on the inner side of the wall portion 65 so as to cover the outer periphery of the optical member 10. The resin member 68 may be formed from a dark colored resin such as a black resin. Examples of the material of the resin member 68 include an epoxy resin, a silicone resin, an acrylate resin, a urethane resin, a phenol resin, a BT resin, or the like including a filler such as a light-absorbing filler, a dark colored pigment such as carbon black, and the like. By providing the resin member 68 configured as such, wiring and the like can be protected.

### Fourth Embodiment

As illustrated in FIGS. 6A to 6E, a light-emitting device 70 according to the fourth embodiment includes a package 72 and the optical member 20. The plurality of wavelength conversion members 3 (the first wavelength conversion member 3 and the one or the plurality of second wavelength conversion members 32) are disposed in the optical member 20. As illustrated in FIG. 6E, the light-emitting device 70 further includes a plurality of the semiconductor laser elements 61. Each semiconductor laser element 61 is preferably mounted on the submount 67. In the light-emitting device 70, a plurality of the light reflecting members 63 are disposed for causing the laser beam to enter the wavelength conversion portion 1 of each wavelength conversion member 3. Other than that, the light-emitting device 70 has substantially the same configuration as the light-emitting device 60.

In the light-emitting device 70, the plurality of semiconductor laser elements 61 can be individually driven. The plurality of semiconductor laser elements 61 may be electrically connected in series and may be driven together.

In the optical member 20, the first wiring layer provided on each of the plurality of wavelength conversion members 3 can individually be made electrically conductive. By connecting a plurality of wires 28 as illustrated in FIG. 6C, the plurality of wavelength conversion members 3 can be electrically connected together, the plurality of wavelength conversion members 3 can be electrically individually connected, or the plurality of wavelength conversion members 3 sequentially arranged in series can be electrically connected.

In the light-emitting device 70 connected to the wires 28 as illustrated in FIG. 6C, each of the plurality of second wiring layers 14 is connected to an electrode 76 of different packages 72 by the wires 28. That is, the wire 28 that is joined to the second wiring layer 14 is joined to the electrode 76 different from the electrode 76 to which the wire 28 joined to another second wiring layer 14 is joined. When a current is passed through the two electrodes 76, in a top view, current flows through all of the wavelength conversion members 3 located between the second wiring layer 14 joined to the wire 28 joined to one of the electrodes 76 and the second wiring layer 14 joined to the wire 28 joined to the other electrode 76. Accordingly, in a top view, all of the wavelength conversion members 3 located between the second wiring layer 14 joined to the wire 28 joined to one of the electrodes 76 and the second wiring layer 14 joined to the wire 28 joined to the other electrode 76 form a current path electrically connected in series.

In the optical member 20, the plurality of wavelength conversion members 3 may be collectively connected in series. Such a connection configuration is illustrated in FIG. 6D. In the light-emitting device 70 with the wire 28 connected as illustrated in FIG. 6D, the wires 28 are connected to, of the plurality of second wiring layers 14, the second wiring layers 14 on both ends, and these wires 28 are joined to the electrodes 76 at the other end. Even when electrically connected as such, in a case in which cracking or breaking occurs in one of the plurality of wavelength conversion members 3, because the first wiring layer 13 or the like disposed in the wavelength conversion member 3 breaks, this breakage can be detected and power can stop being sent to the semiconductor laser element.

In the light-emitting device 70, in a top view, the resin member 68 covers the inner side of the package 72 and the outer side of the region where the plurality of wavelength conversion members 3 are disposed. The resin member 68 may not be formed between the plurality of wavelength conversion members 3 disposed side by side. When the gap between the wavelength conversion members 3 is small and the viscosity of the resin is great, it is also conceivable that the resin does not enter into this gap. Even in this case, in a top view, the second wiring layer 14 (light shielding member 6) is provided between the plurality of wavelength conversion members 3 in a top view, and thus the leakage of light from portions other than the wavelength conversion portion 1 can be suppressed.

The optical member and the light-emitting device described in the embodiments can be used in an onboard light source, an illumination light source, and the like.

What is claimed is:

1. An optical member comprising:
a first wavelength conversion member including a wavelength conversion portion and a ceramic portion surrounding lateral surfaces of the wavelength conversion portion; and
a light shielding film arranged on an outer lateral surface of the first wavelength conversion member.

2. The optical member according to claim 1, wherein
the ceramic portion defines a void and has reflectivity for reflecting light emitted from the wavelength conversion portion.

3. The optical member according to claim 1, further comprising
a light-transmitting member having an upper surface, wherein
the first wavelength conversion member is disposed on the upper surface of the light-transmitting member.

4. The optical member according to claim 3, further comprising:
a first wiring layer arranged on a lower surface of the first wavelength conversion member; and
a plurality of second wiring layers arranged on the upper surface of the light-transmitting member, and electrically connected to the first wiring layer.

5. The optical member according to claim 3, further comprising
one or more second wavelength conversion members each including a wavelength conversion portion and a ceramic portion surrounding lateral surfaces of the wavelength conversion portion, wherein
the one or more second wavelength conversion members is disposed on the upper surface of the light-transmitting member.

6. The optical member according to claim 5, wherein
the first wavelength conversion member and the one or more second wavelength conversion members are disposed side by side, and
the ceramic portions of adjacent ones of the first wavelength conversion member and the one or more second wavelength conversion members are spaced apart from each other.

7. The optical member according to claim 6, further comprising
a light shielding member disposed on the upper surface of the light-transmitting member at least a portion between adjacent ones of the first wavelength conversion member and the one or more second wavelength conversion members.

8. The optical member according to claim 5, wherein
the first wavelength conversion member and the one or more second wavelength conversion members are aligned in a first direction so that the wavelength conversion portions of the first wavelength conversion member and the one or more second wavelength conversion members are arranged with a pitch in the first direction ranging from 2 times to 5 times a width in the first direction of each of the wavelength conversion portions.

9. The optical member according to claim 7, wherein
the first wavelength conversion member and the one or more second wavelength conversion members are aligned in a first direction so that adjacent ones of the first wavelength conversion member and the one or more second wavelength conversion members are spaced apart by a distance in the first direction ranging from ⅕ times to 1/1 times a width in the first direction of the wavelength conversion portion of each of the first wavelength conversion member and the one or more second wavelength conversion members.

10. The optical member according to claim 5, further comprising:
a first wiring layer arranged on a lower surface of the first wavelength conversion member and a lower surface of each of the one or more second wavelength conversion members; and
a plurality of second wiring layers arranged on the upper surface of the light-transmitting member, and electrically connected to the first wiring layer.

11. The optical member according to claim 8, further comprising:
a first wiring layer arranged on a lower surface of the first wavelength conversion member and a lower surface of each of the one or more second wavelength conversion members; and
a plurality of second wiring layers arranged on the upper surface of the light-transmitting member, and electrically connected to the first wiring layer, wherein
the second wiring layers are arranged side by side in the first direction.

12. The optical member according to claim 10, wherein
the second wiring layers and the first wiring layer of each of the first wavelength conversion member and the one or more second wavelength conversion members are electrically connected in series.

13. The optical member according to claim 1, wherein
the light shielding film is arranged on an upper surface of the ceramic portion and an outer lateral surface of the ceramic portion but not arranged on at least a portion of an upper surface of the wavelength conversion portion.

14. A light-emitting device comprising:
the optical member according to claim 1;
a package including a base portion and a wall portion extending from the base portion; and
a plurality of semiconductor laser elements disposed in a space defined by the package and the optical member.
